(19) United States
(12) Patent Application Publication
(10) Pub. No.: US 2009/0321870 A1
(43) Pub. Date: Dec. 31, 2009

(54) SHUTTLE WAFER AND METHOD OF FABRICATING THE SAME

(75) Inventors: Weng-Yi Chen, Hsinchu County (TW); Wen-Sheng Chien, Hsinchu City (TW)

Correspondence Address: NORTH AMERICA INTELLECTUAL PROPERTY CORPORATION, P.O. BOX 506, MERRIFIELD, VA, 22116, US

(73) Assignee: UNITED MICROELECTRONICS CORP., Hsinchu (TW)

(21) Appl. No.: 12/147,990

(22) Filed: Jun. 27, 2008

(51) Int. Cl. H01L 21/70; H01L 27/00

(52) U.S. Cl. 257/499; 438/400; 257/E21.532; 257/E27.001

(57) ABSTRACT

A method of fabricating a shuttle wafer is provided. First, a wafer including a number of shots is provided. Each of the shots includes a number of dies. A material layer is then formed on the wafer. After that, a shuttle mask having a number of IC designs is provided. A first IC design corresponds to a first die of each of the shots. A portion of the IC designs on the shuttle mask is covered for exposing the first IC design. Thereafter, the first IC designs of the shuttle mask are transferred onto the material layer, so as to form at least an effective IC pattern on the first die of each of the shots and to form an ineffective IC pattern on each of the other dies of each of the shots.

### BACKGROUND OF THE INVENTION

1. Field of the Invention

The present invention generally relates to a wafer and a method of fabricating the same, and more particularly to a shuttle wafer and a method of fabricating the same.

2. Description of Related Art

As fabrication of semiconductors is in progress, complexity of manufacturing a mask of a die is raised accordingly, and so are the costs of fabricating the mask. In order to remove a cost barrier of fabricating a test mask required by a test die and to reduce manufacturing costs of the test die, semiconductor foundries put dies designed by different customers on a shuttle mask, so as to allow the customer to share the mask costs. After the shuttle wafer is cut, individual dies requested by respective customers become available to each of them. Nevertheless, not the die individually owned by a certain customer but the full shuttle wafer is usually delivered to each of the customers in a wafer level testing stage or a packaging stage. By doing so, the die designed by the certain customer might be exposed to other customers who share the same shuttle wafer, raising proprietary information concerns. One of the conventional solutions rests in destroying the other die designs in the same shuttle wafer through performing a laser process or the like, such that the certain customer is not able to obtain information of others' integrated circuit (IC) designs by means of the shuttle wafer. However, the laser process or the like implemented for removing others' IC designs on the same shuttle wafer may bring about an increase in manufacturing costs, which is rather uneconomic.

### SUMMARY OF THE INVENTION

The present invention is directed to a method of fabricating a shuttle wafer including an effective IC design and a plurality of ineffective IC designs.

The present invention is further directed to a shuttle wafer provided to a certain customer without exposing proprietary information to the other customers.

The present invention provides a method of manufacturing a shuttle wafer. In the method, a material layer is formed on a wafer at first. The wafer includes a plurality of shots, and each of the shots includes a plurality of dies. After that, a shuttle mask having a plurality of IC designs is provided. A first IC design in the IC designs corresponds to a first die of each of the shots. Next, a portion of the IC designs on the shuttle mask for exposing the first IC design is covered. Thereafter, the first IC designs of the shuttle mask is transferred onto the material layer, so as to form at least an effective IC pattern on the first die of each of the shots and to form an ineffective IC pattern on the each of the other dies of each of the shots.

According to an embodiment of the present invention, the material layer includes an insulating layer.

According to an embodiment of the present invention, the effective IC pattern includes a bonding pad opening pattern, a contact opening pattern, or a via opening pattern, while the insulating layer having the ineffective IC pattern is an unpatterned insulating layer.

According to an embodiment of the present invention, the material layer includes a conductive layer.

According to an embodiment of the present invention, the effective IC pattern includes a bonding pad pattern, a metal line pattern, a word line pattern, a bit line pattern, or an electrode pattern, while the conductive layer having the ineffective IC pattern is an unpatterned conductive layer.

According to an embodiment of the present invention, the effective IC pattern includes an implantation region pattern, while the material layer having the ineffective IC pattern is the material layer without the implantation region pattern.

According to an embodiment of the present invention, the method of covering the portion of the IC designs on the shuttle mask includes using a shutter.

According to an embodiment of the present invention, the method of fabricating the shuttle wafer further includes following steps. First, a dummy mask having a plurality of dummy designs is provided. A portions of dummy designs corresponding to the first die are then covered. Next, the other portions of dummy designs corresponding to the dies excluding the first die are transferred onto the material layer, so as to form a dummy pattern on each of the dies excluding the first die.

According to an embodiment of the present invention, the first die includes a plurality of dies.

The present invention further provides a shuttle wafer including a wafer and a material layer. The wafer includes a plurality of shots, and each of the shots includes a plurality of dies. The material layer is disposed on the wafer. The material layer on a first die of each of the shots has an effective IC pattern, whereas the material layer on the other dies of each of the shots is unpatterned, serving as an ineffective IC pattern.

According to an embodiment of the present invention, the material layer includes an insulating layer.

According to an embodiment of the present invention, the effective IC pattern includes a bonding pad opening pattern, a contact opening pattern, or a via opening pattern.

According to an embodiment of the present invention, the material layer includes a conductive layer.

According to an embodiment of the present invention, the effective IC pattern includes a bonding pad pattern, a metal line pattern, a word line pattern, a bit line pattern, or an electrode pattern.

According to an embodiment of the present invention, the effective IC pattern includes an implantation region pattern.

According to an embodiment of the present invention, the first die includes a plurality of dies.

The present invention further provides a shuttle wafer including a wafer and a material layer. The wafer includes a plurality of shots, and each of the shots includes a plurality of dies. The material layer is disposed on the wafer. The material layer on a first die of each of the shots has an effective IC pattern, whereas the material layer on the other dies of each of the shots has a dummy pattern, serving as an ineffective IC pattern.

According to an embodiment of the present invention, the material layer includes an insulating layer.

According to an embodiment of the present invention, the effective IC pattern includes a bonding pad opening pattern, a contact opening pattern, or a via opening pattern.

According to an embodiment of the present invention, the material layer includes a conductive layer.

According to an embodiment of the present invention, the effective IC pattern includes a bonding pad pattern, a metal line pattern, a word line pattern, a bit line pattern, or an electrode pattern.

According to an embodiment of the present invention, the effective IC pattern includes an implantation region pattern.

According to an embodiment of the present invention, the first die includes a plurality of dies.

The shuttle wafer of the present invention includes one effective IC pattern and a plurality of ineffective IC patterns, such that the shuttle wafer provided to the certain customer merely reveals the IC design owned by said customer, while the other IC designs owned by the other customers are ineffective. Thereby, the IC design possessed by one customer is not improperly exposed to the other customers who share the same shuttle wafer. In addition, the effective and ineffective IC patterns can be formed on the shuttle wafer by covering only one portion of the shuttle mask in the process of fabricating the shuttle wafer. Without additionally increasing the number of the masks or performing destructive processes on the IC patterns, the costs for manufacturing the shuttle wafer shared by respective customers can be reduced.

In order to make the aforementioned and other objects, features and advantages of the present invention more comprehensible, several embodiments accompanied with figures are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIGS. 1A and 1B are top views respectively depicting a wafer and a shuttle wafer according to a first embodiment of the present invention.

FIGS. 2A through 2D are schematic cross-sectional views depicting a portion of the wafer according to the first embodiment of the present invention.

FIG. 3A is a schematic view depicting a shuttle mask used for forming a bonding pad pattern according to an embodiment of the present invention.

FIG. 3B is a schematic view depicting the shuttle mask of FIG. 3A which is covered.

FIG. 3A-1 depicts a shuttle mask used for forming a bonding pad opening pattern according to an embodiment of the present invention.

FIG. 3B-1 is a schematic view depicting the shuttle mask of FIG. 3A-1 which is covered.

FIGS. 4A through 4C are schematic cross-sectional views depicting a portion of a wafer according to a second embodiment of the present invention.

FIG. 5 is schematic cross-sectional views depicting a portion of a wafer according to a third embodiment of the present invention.

FIGS. 6A through 6C are schematic cross-sectional views depicting a portion of a wafer according to a fourth embodiment of the present invention.

FIG. 7A is a schematic top view depicting a dummy mask according to the fourth embodiment of the present invention.

FIG. 7B is a schematic view depicting the dummy mask of FIG. 7A which is covered.

FIG. 8 is a schematic top view depicting a shuttle wafer having a dummy pattern according to the fourth embodiment of the present invention.

FIG. 9 is schematic cross-sectional views depicting a portion of a wafer according to a first embodiment of the present invention adding a dummy patterning process using a dummy mask.

FIG. 10 is schematic cross-sectional views depicting a portion of a wafer according to a third embodiment of the present invention adding a dummy patterning process using a dummy mask.

### DESCRIPTION OF EMBODIMENTS

By using a shuttle mask disclosed in the present invention, only an IC design of a shuttle wafer provided to a certain customer is an effective IC pattern, while the other IC designs owned by the other customers who share the same shuttle wafer are ineffective. In a first embodiment provided hereinafter, a method of fabricating the shuttle wafer is disclosed to determine if the IC design is the effective IC pattern or the ineffective IC pattern in a stage of manufacturing bonding pads. In a second embodiment provided hereinafter, a method of fabricating the shuttle wafer is disclosed to determine if the IC design is the effective IC pattern or the ineffective IC pattern in a stage of manufacturing bonding pad openings. In a third embodiment provided hereinafter, a method of fabricating the shuttle wafer is disclosed to determine if the IC design is the effective IC pattern or the ineffective IC pattern in a stage of manufacturing implantation regions.

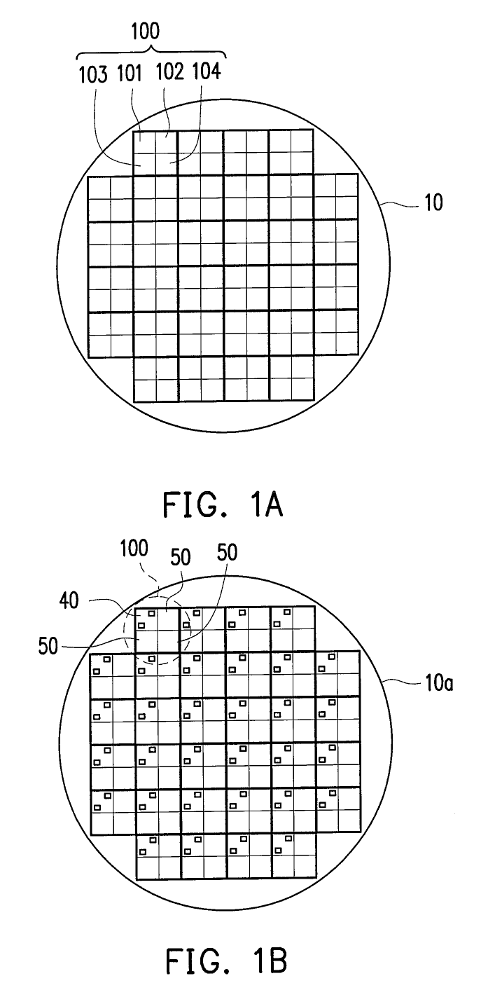

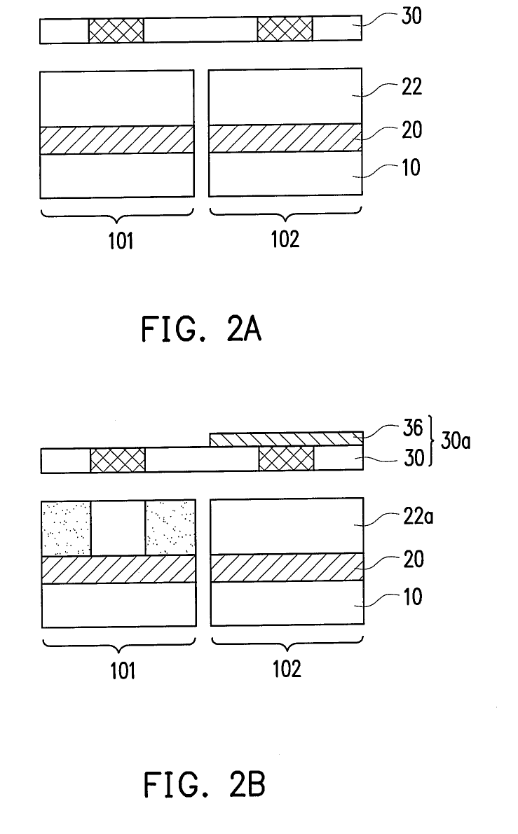

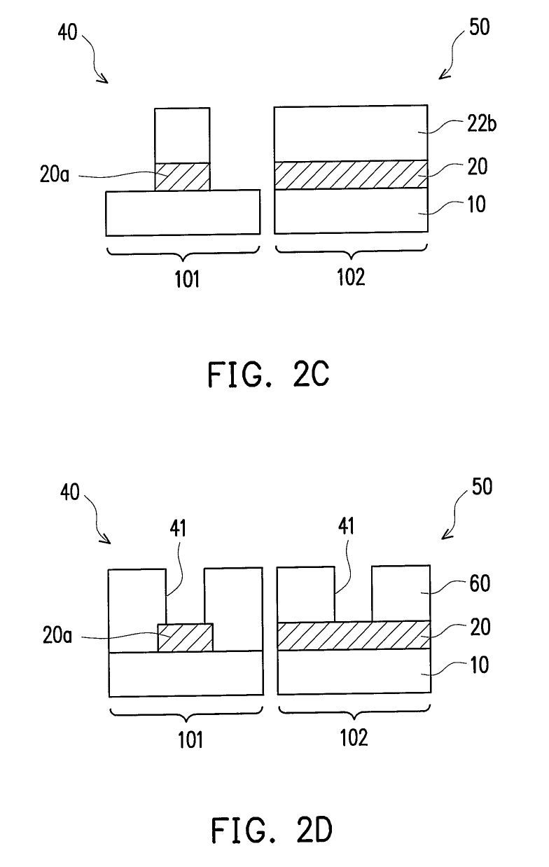

FIGS. 1A and 1B are top views respectively depicting a wafer and a shuttle wafer according to a first embodiment of the present invention. FIGS. 2A through 2D are schematic cross-sectional views depicting a portion of the wafer according to the first embodiment of the present invention. FIG. 3A is a schematic view depicting a shuttle mask used for forming a bonding pad pattern according to an embodiment of the present invention. FIG. 3B is a schematic view depicting the shuttle mask of FIG. 3A which is covered. For clarification purposes, a die 101 and a die 102 are represented in the drawings as two separated regions. Besides, the schematic cross-sectional views of a die 103 and of a die 104 are similar to that of the die 102 and not shown.

Referring to FIG. 1A, a wafer 10 including a plurality of shots 100 is provided at first. Each of the shots 100 includes a plurality of dies 101, 102, 103, and 104. In the present embodiment, the dies 101, 102, 103, and 104 are assumed to be possessed by customers A, B, C, and D, respectively. Even though all the dies in FIG. 1A have the same size. It is noted that all the dies in shot 100 can have different sizes or part of them can share the same size. In addition, although each of the dies 101, 102, 103, and 104 is shown as a die, each of the dies 101, 102, 103, and 104 may include a plurality of dies, in the other words, a customers may possess a plurality of dies.

Referring to FIG. 2A, a conductive layer 20 is then formed on the wafer 10. The conductive layer 20 is made of conductive materials including doped-polysilicon, polycide, aluminum, tungsten, titanium, and so on, for example. A method of forming the conductive layer 20 includes performing a chemical vapor deposition (CVD) process, a sputtering process, and so forth. There may exist a plurality of material layers (not shown) disposed between the wafer 10 and the conductive layer 20 on each of the dies 101, 102, 103, and 104 in each of the shots 100. Here, the material layers (not shown) respectively have IC patterns required by the individual customers A, B, C, and D. Next, a photoresist layer 22 is formed on the conductive layer 20. The photoresist layer 22 of the present embodiment is, for example, positive photoresist.

Referring to FIGS. 2A and 3A together, a shuttle mask 30 is then provided. In the present embodiment, the shuttle mask 30 has a plurality of IC designs 31, 32, 33, and 34 for forming bonding pad patterns. The IC designs 31, 32, 33, and 34 are respectively provided by the customers A, B, C, and D.

Next, referring to FIGS. 2B and 3B together, a portion of the shuttle mask 30 is covered for forming a covered shuttle mask 30a. In the present embodiment, a shutter 36 is used to cover the IC designs 32, 33, and 34 of the shuttle mask 30 respectively possessed by the customers B, C, and D, while the IC design 31 owned by the customer A remains uncovered.

Thereafter, referring to FIGS. 2B and 3B together, an exposure process is performed on the photoresist layer 22 with use of the covered shuttle mask 30a, so as to form a photoresist layer 22a. The bonding pad pattern transferred from the shuttle mask 30a is then formed in the photoresist layer 22a above the die 101.

Afterwards, referring to FIGS. 2B and 2C together, a development process is performed on the photoresist layer 22a, so as to transfer the IC design 31 of the covered shuttle mask 30a onto a photoresist layer 22b.

Referring to FIGS. 2C and 3B together, the photoresist layer 22b is then taken as a mask for transferring the pattern of the photoresist layer 22b onto the conductive layer 20, such that the bonding pad pattern is formed on the die 101. Here, the bonding pad pattern is an effective IC pattern 40. On the other hand, since the IC designs 32, 33, and 34 of the covered shuttle mask 30a are hidden and are unlikely to be transferred onto the photoresist layer 22b, the conductive layer 20 on the other dies 102, 103, and 104 cannot be patterned, such that ineffective IC patterns 50 are formed.

Next, referring to FIGS. 1B and 2D together, the photoresist layer 22b is removed. Thereafter, an insulating layer 60 is formed on the wafer 10. In the present embodiment, the insulating layer 60 acts as a passivation layer. A material of the insulating layer 60 is, for example, silicon oxide, undoped silicate glass (USG), boron phosphorous silicate glass (BPSG), or a dielectric material stacked by phosphorous silicate glass (PSG) and silicon nitride.

FIG. 3A-1 is a schematic view illustrating a shuttle mask used for forming a bonding pad opening pattern.

Referring to FIGS. 3A-1 and 2D together, a shuttle mask 80 having IC designs 81, 82, 83, and 84 respectively provided by the customers A, B, C, and D is used for pattern transfer. Here, the IC designs 81, 82, 83, and 84 are taken for forming the bonding pad opening patterns. With use of the shuttle mask 80, the fabrication of a shuttle wafer 10a is completed by equipping the passivation layer 60 of each of the dies 101, 102, 103, and 104 with a required bonding pad opening pattern 41.

According to the present embodiment, in each of the shots 100 of the shuttle wafer 10a, the effective IC pattern 40 on the die 101 is the bonding pad pattern, whereas the ineffective IC pattern 50 on each of the dies 102, 103, and 104 is the unpatterned conductive layer 20. Only the IC design 31 owned by the customer A becomes the effective IC pattern 40. Hence, when the shuttle wafer 10a is provided to the customer A in a wafer testing stage or in a wafer package stage, the information of the IC designs 32, 33, and 34 respectively possessed by the customers B, C, and D is not accessible to the customer A through the shuttle wafer 10a. That is to say, the IC design possessed by one customer will not be improperly exposed to the other customers who share the shuttle wafer 10a, thus preventing revelation of proprietary information. Besides, in the present embodiment, the ineffective IC patterns 50 on the dies 102, 103, and 104 of the customers B, C, and D are formed by covering the IC designs of only one mask owned by the respective customers B, C, and D. Hence, additional processes for destroying the IC patterns are not necessary, and the manufacturing costs of the shuttle wafer are not increased significantly.

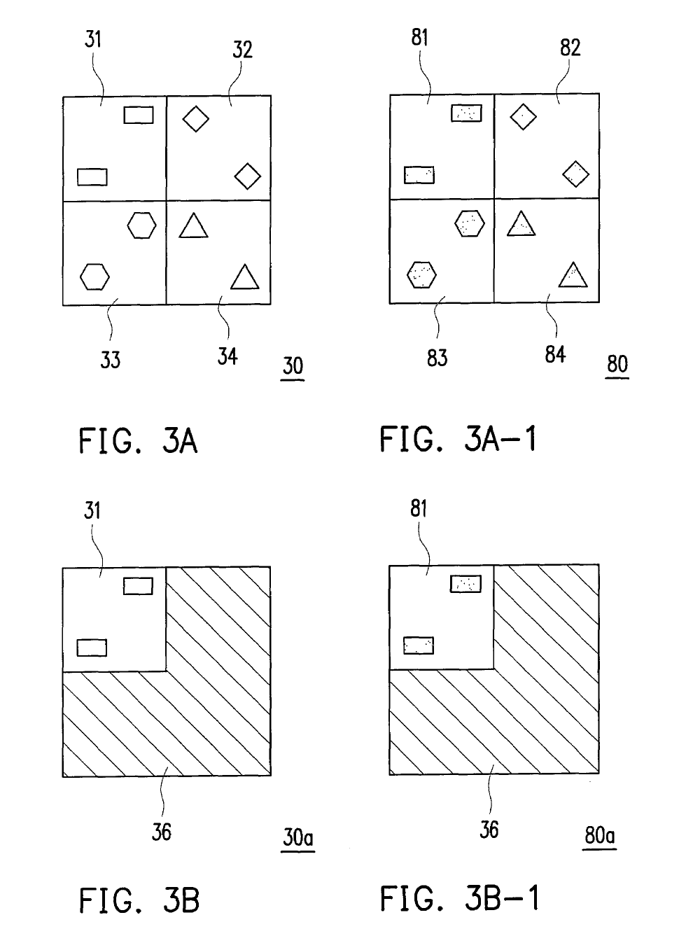

FIGS. 4A through 4C are schematic cross-sectional views depicting a portion of a wafer according to a second embodiment of the present invention. FIG. 3A-1 is a schematic view illustrating a shuttle mask used for forming a bonding pad opening pattern. FIG. 3B-1 is a schematic view depicting the shuttle mask of FIG. 3A-1 which is covered.

Referring to FIGS. 4A and 3A, the shuttle mask 30 having the IC designs 31, 32, 33, and 34 respectively provided by the customers A, B, C, and D is used for pattern transfer. Here, the IC designs 31, 32, 33, and 34 are used to form the bonding pad patterns. The conductive layer 20a having the bonding pad pattern is formed on each of the dies 101, 102, 103, and 104, respectively.

Thereafter, the insulating layer 60 is formed on the wafer 10. The insulating layer 60 is, for example, made of a dielectric material including silicon oxide, silicon nitride, USG, BPSG, PSG, or combination thereof. In the present embodiment, the insulating layer 60 is used for forming the passivation layer having the bonding pad opening pattern. Next, a photoresist layer 92 is formed on the insulating layer 60. The photoresist layer 92 of the present embodiment is, for example, a positive photoresist.

Referring to FIGS. 3A-1 and 4A together, the shuttle mask 80 is then provided. In the present embodiment, the shuttle mask 80 has the IC designs 81, 82, 83, and 84 respectively provided by the individual customers A, B, C, and D. Here, the IC designs 81, 82, 83, and 84 are used to form the bonding pad opening patterns.

Referring to FIGS. 3B-1 and 4B together, a portion of the shuttle mask 80 is covered for forming a covered shuttle mask 80a. In the present embodiment, the shutter 36 is used to cover the IC designs 82, 83, and 84 respectively possessed by the customers B, C, and D, while the IC design 81 owned by the customer A remains uncovered.

Thereafter, referring to FIG. 4B, an exposure process is performed on the photoresist layer 92 with use of the covered shuttle mask 80a, so as to form a photoresist layer 92a. The bonding pad opening pattern transferred from the shuttle mask 80a is then formed in the photoresist layer 92a above the die 101.

Afterwards, referring to FIGS. 4B and 4C together, a development process is performed on the photoresist layer 92a, so as to transfer the IC design 81 of the covered shuttle mask 80a onto a photoresist layer 92b.

Referring to FIG. 4C, the photoresist layer 92b is then taken as a mask for transferring the IC pattern 81 of the covered shuttle mask 80a onto the insulating layer 60, such that the bonding pad opening pattern is formed on the die 101. Here, the bonding pad opening pattern is the effective IC pattern 40. On the other hand, since the IC designs 82, 83, and 84 of the covered shuttle mask 80a are hidden and are unlikely to be transferred, the insulating layer 60 on the other dies 102, 103, and 104 cannot be patterned, such that the ineffective IC patterns 50 are formed. After that, the photoresist layer 92b is removed, and the fabrication of the shuttle wafer 10a (shown in FIG. 1B) is completed.

In no consideration of an issue of alignment, the conductive layer can also be used to form a metal line, a word line, a bit line, or an electrode in any layer of interconnects. Moreover, it is not limited for the insulating layer to act as the passivation layer only. Namely, the insulating layer can also serve as an inner dielectric layer or an interlayer dielectric layer. Therefore, not only the bonding pad opening but also a contact opening or a via opening can be formed. That is to say, any shuttle mask in the aforesaid process of manufacturing the shuttle wafer can be the mask which is partly covered.

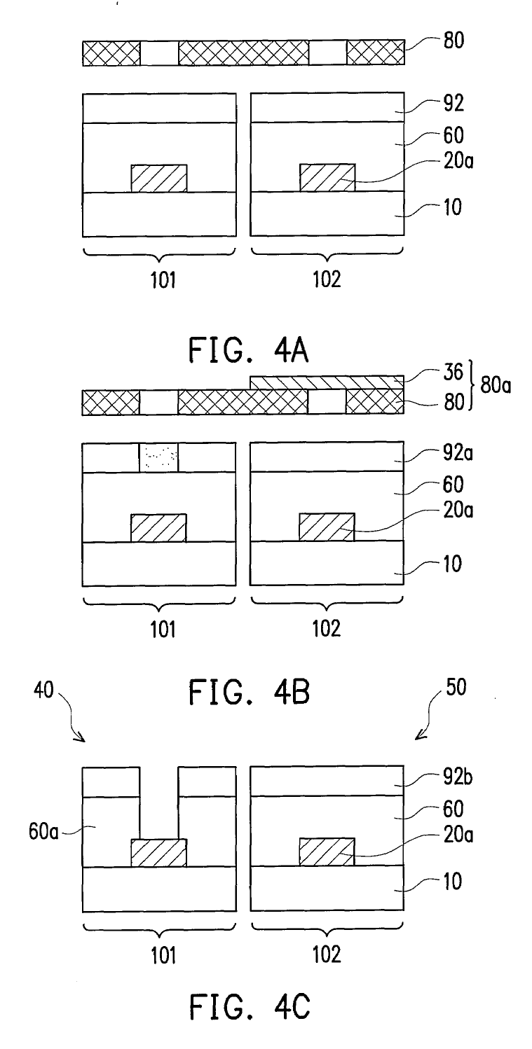

FIG. 5 is schematic cross-sectional views depicting a portion of the wafer according to the third embodiment of the present invention. Referring to FIG. 5, it is not limited for the effective IC pattern 40 according to the present invention formed in the conductive layer or insulating layer. In an embodiment, the effective IC pattern 40 can be formed in a material layer 160 such as a semiconductor layer. In another embodiment, the effective IC pattern 40 can be formed in the wafer 10. The effective IC pattern 40 can be an implantation region pattern 162 in the material layer 160, while the ineffective IC patterns 50 is the material layer 160 without the implantation region pattern 162. The implantation region 162 is a doped region, for example, such as a source region, a drain region, a well, a doped region of a diode, and so on. The fabrication method of the implantation region pattern 162 is similar to the aforesaid method in the second embodiment, while the IC designs of shuttle mask is used for forming implantation region pattern. The shutter is used to cover the IC designs respectively possessed by the customers B, C, and D, while the IC design owned by the customer A remains uncovered. Next, an exposure process is performed on the photoresist layer 192 with use of the covered shuttle mask. Thereafter, a development process is performed on the photoresist layer 192, so as to form an opening pattern 194 in the photoresist layer 192 on the die 101, and the photoresist layer 192 on the other dies 102, 103, and 104 cannot be patterned. Afterwards, an ion implantation process 196 is performed using the photoresist layer 192 serving as a mask layer, so as to form the implantation region pattern 162 in the material layer 160 on the die 101, rather than on the other dies 102, 103, and 104. The implantation region pattern 162 in the material layer 160 on the die 101 serves as the effective IC patterns 40, and the material layer 160 on the other dies 102, 103, and 104 without the implantation region pattern 162 serves as the ineffective IC patterns 50.

In the subsequent processes, the photoresist layer 192 is removed and then the IC designs on shuttle masks possessed by the customers A, B, C, and D are transform to dies 101, 102, 103, and 104, respectively to complete the fabrication of the shuttle wafer 10a as shown in FIG. 1B.

In the aforesaid embodiments, only one shuttle mask is covered, while it is also likely to cover more than one shuttle mask. Besides, it is not limited for the conductive layer to be used for forming the bonding pad only. In addition, if the adjacent dies (e.g. the dies 101 and 102) belong to the same customer, the effective IC pattern can be formed on the adjacent dies, respectively.

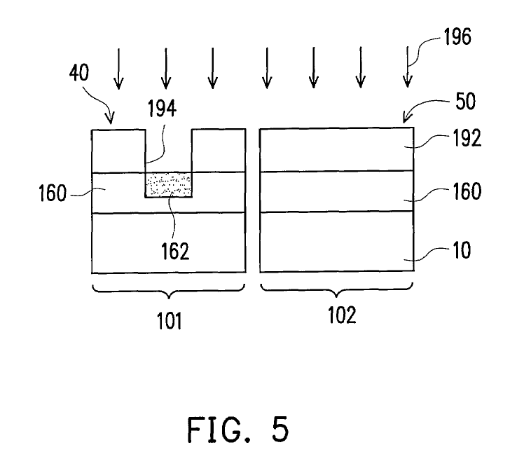

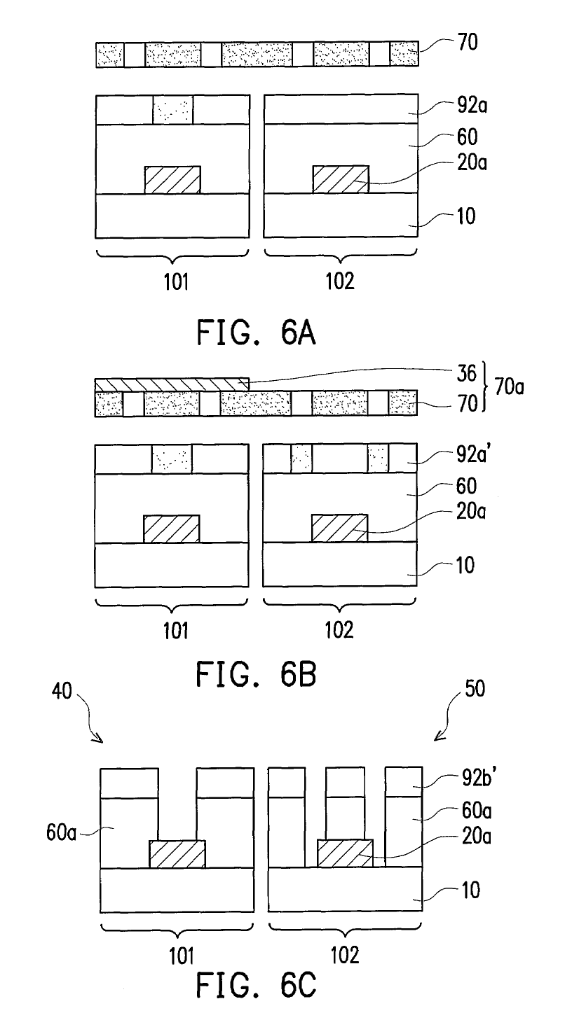

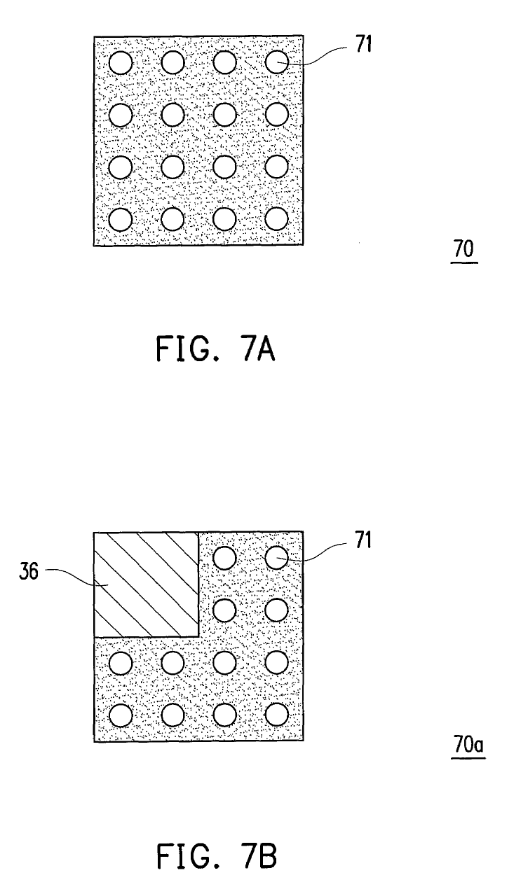

FIGS. 6A through 6C are schematic cross-sectional views depicting a portion of a wafer according to a fourth embodiment of the present invention. FIG. 7A is a schematic top view depicting a dummy mask according to the fourth embodiment of the present invention. FIG. 7B is a schematic view depicting the dummy mask of FIG. 7A which is covered. FIG. 8 is a schematic top view depicting a shuttle wafer having a dummy pattern according to the fourth embodiment of the present invention. In the present embodiment, the method for forming the effective and ineffective IC patterns on the shuttle wafer by performing two exposure process and one development process on the same photoresist layer is provided.

Referring to FIGS. 6A and 6A, through processes as the second embodiment, the bonding pad opening pattern transferred from the shuttle mask 80a is formed in the photoresist layer 92a above the die 101. Next, a dummy mask 70 is provided. The dummy mask 70 has a plurality of dummy designs 71 uniformly distributed on the dummy mask 70. In this embodiment, the dummy designs 71 are opening patterns. In another embodiment, the dummy designs 71 is an opaque pattern with bar or block type.

Referring to FIGS. 6B and 6B together, the dummy designs 71 corresponding to the die 101 and disposed in the dummy mask 70 are covered, while the other dummy designs 71 corresponding to the dies 102, 103, and 104 are exposed, so as to form a covered dummy mask 70a. Here, the shutter 36 is used to cover the dummy design 71 corresponding to the die 101 and disposed in the dummy mask 70.

Referring to FIG. 6B, a second exposure process is then performed on the photoresist layer 92a with use of the covered dummy mask 70a, so as to form a photoresist layer 92a′. In the photoresist layer 92a′, the bonding pad opening pattern transferred from the covered shuttle mask 80a is formed above the die 101, while the dummy patterns transferred from the covered dummy mask 70a are formed above the dies 102, 103, and 104.

Next, referring to FIG. 6C, the development process is performed on the photoresist layer 92a′, so as to transfer the IC design 81 of the covered shuttle mask 80a and the dummy designs 71 of the covered dummy mask 70a onto a photoresist layer 92b′. Here, the bonding pad opening is formed in the photoresist layer 92b′ above the die 101, while the dummy patterns transferred from the covered dummy mask 70a are formed above the dies 102, 103, and 104.

Thereafter, the photoresist layer 92b′ is taken as a mask for transferring the bonding pad opening pattern and the dummy patterns onto an insulating layer 60a, so as to form the bonding pad opening pattern on the die 101. Here, the bonding pad opening pattern is the effective IC pattern 40. On the other hand, the dummy pattern is formed on each of the dies 102, 103, and 104, respectively. Here, the dummy pattern is the ineffective IC pattern 50.

After that, referring to FIG. 8, the photoresist layer 92b′ is removed, and the fabrication of the shuttle wafer 10a is then completed. In each of the shots 100 of the shuttle wafer 10a′, the effective IC pattern of the die 101 is the bonding pad opening pattern, while the ineffective IC pattern 50 of each of the other dies 102, 103, and 104 is the dummy pattern.

According to the present embodiment, two exposure processes and one development process are performed on the same photoresist layer 92, and the patterns of the formed photoresist layer 92b′ are transferred to the shuttle wafer 10a′. Thereby, the density of the patterns on the shuttle wafer 10a′ can be uniformed. As such, the occurrence of a photo, etch or CMP (chemical mechanical polish) loading effect on the shuttle wafer 10a′ can be prevented, and the reliability of devices in the shuttle wafer 10a′ can be further improved. In addition, the bonding pad opening pattern and the dummy pattern are simultaneously formed in the process of fabricating the bonding pad opening pattern according to the present embodiment. Nevertheless, the effective IC pattern and the dummy pattern can be formed at the same time in any step of the aforesaid manufacturing processes for determining if the IC design turns out to be the effective IC pattern or the ineffective IC pattern.

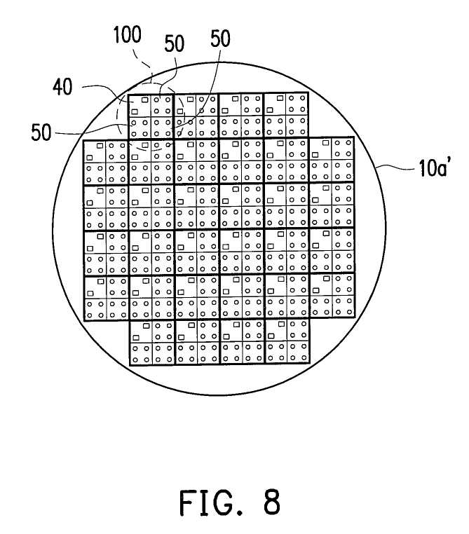

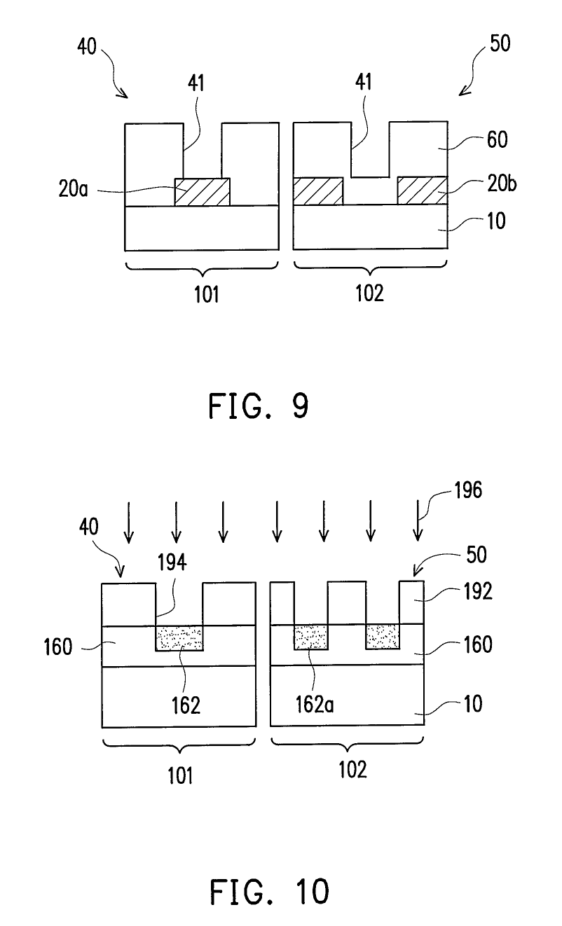

FIG. 9 is schematic cross-sectional views depicting a portion of a wafer 10a′ according to a first embodiment of the present invention adding a dummy patterning process using a dummy mask. Referring to FIG. 9, the conductive layer 20a on die 101 has the boning pad pattern, which is the effective IC pattern 40. The conductive layer 20b on die 102 has a dummy pattern, which is the ineffective IC pattern 50. FIG. 10 is schematic cross-sectional views depicting a portion of a wafer 10a′ according to a third embodiment of the present invention adding a dummy patterning process using a dummy mask. Referring to FIG. 10, the material layer 160 on die 101 has the implantation region pattern 162, which is the effective IC pattern 40. The material layer 160 on die 102 has a dummy pattern 162a, which is the ineffective IC pattern 50.

Moreover, the dummy mask is applicable to any of the manufacturing processes as provided hereinbefore, so as to reduce the costs of the dummy mask shared by the customers.

To sum up, one effective IC pattern and a plurality of ineffective IC patterns are formed on the shuttle wafer by covering a portion of the shuttle mask in the process of fabricating the shuttle wafer as disclosed in the present invention. Thereby, the IC design possessed by one customer is not improperly exposed to the other customers who share the same shuttle wafer, thus affirming the design confidentiality. In addition, the effective and ineffective IC patterns can be formed by covering only one portion of the shuttle mask in the process of fabricating the shuttle wafer. Without additionally increasing the number of the shuttle mask or performing destructive processes on the IC patterns, the costs for manufacturing the shuttle wafer shared by respective customers can be reduced.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A method of fabricating a shuttle wafer, comprising:
providing a wafer comprising a plurality of shots, each of the shots comprising a plurality of dies;
forming a material layer on the wafer;
providing a shuttle mask having a plurality of integrated circuit (IC) designs, wherein a first IC design corresponds to a first die of each of the shots;
covering a portion of the IC designs on the shuttle mask for exposing the first IC design; and
transferring the first IC designs of the shuttle mask onto the material layer, so as to form an effective IC pattern on the first die of each of the shots and to form an ineffective IC pattern on the each of the other dies of each of the shots.

2. The method of fabricating the shuttle wafer as claimed in claim 1, wherein the material layer comprises an insulating layer.

3. The method of fabricating the shuttle wafer as claimed in claim 2, wherein the effective IC pattern includes a bonding pad opening pattern, a contact opening pattern, or a via opening pattern, while the insulating layer having the ineffective IC pattern is an unpatterned insulating layer.

4. The method of fabricating the shuttle wafer as claimed in claim 1, wherein the material layer comprises a conductive layer.

5. The method of fabricating the shuttle wafer as claimed in claim 4, wherein the effective IC pattern includes a bonding pad pattern, a metal line pattern, a word line pattern, a bit line pattern, or an electrode pattern, while the conductive layer having the ineffective IC pattern is an unpatterned conductive layer.

6. The method of fabricating the shuttle wafer as claimed in claim 1, wherein the effective IC pattern includes an implantation region pattern, while the material layer having the ineffective IC pattern is the material layer without the implantation region pattern.

7. The method of fabricating the shuttle wafer as claimed in claim 1, wherein the method of covering the portion of the IC designs on the shuttle mask comprises using a shutter.

8. The method of fabricating the shuttle wafer as claimed in claim 1, further comprising:
providing a dummy mask having a plurality of dummy designs;
covering a portions of the dummy designs corresponding to the first die; and
transferring the other portions of dummy designs corresponding to the dies excluding the first die to the material layer and, so as to form a dummy pattern on each of the dies excluding the first die.

9. The method of fabricating the shuttle wafer as claimed in claim 1, wherein the first die comprises a plurality of dies.

10. A shuttle wafer, comprising:
a wafer comprising a plurality of shots, each of the shots comprising a plurality of dies; and
a material layer disposed on the wafer, wherein
the material layer on a first die of each of the shots has the effective IC pattern, and
the material layer on the other dies of each of the shots is unpatterned, serving as an ineffective IC pattern.
an insulating layer.

12. The shuttle wafer as claimed in claim 11, wherein the effective IC pattern includes a bonding pad opening pattern, a contact opening pattern, or a via opening pattern.

13. The shuttle wafer as claimed in claim 10, wherein the material layer comprises a conductive layer.

14. The shuttle wafer as claimed in claim 13, wherein the effective IC pattern includes a bonding pad pattern, a metal line pattern, a word line pattern, a bit line pattern, or an electrode pattern.

15. The shuttle wafer as claimed in claim 10, wherein the effective IC pattern includes an implantation region pattern.

16. The method of fabricating the shuttle wafer as claimed in claim 10, wherein the first die comprises a plurality of dies.

17. A shuttle wafer, comprising:
a wafer comprising a plurality of shots, each of the shots comprising a plurality of dies; and
a material layer disposed on the wafer, wherein
the material layer of a first die of each of the shots has the effective IC pattern, and
the material layer of the other dies of each of the shots has a dummy pattern, serving as an ineffective IC pattern.

18. The shuttle wafer as claimed in claim 17, wherein the material layer comprises an insulating layer.

19. The shuttle wafer as claimed in claim 18, wherein the effective IC pattern includes a bonding pad opening pattern, a contact opening pattern, or a via opening pattern.

20. The shuttle wafer as claimed in claim 17, wherein the material layer comprises a conductive layer.

21. The shuttle wafer as claimed in claim 20, wherein the effective IC pattern includes a bonding pad pattern, a metal line pattern, a word line pattern, a bit line pattern, or an electrode pattern.

22. The shuttle wafer as claimed in claim 17, wherein the effective IC pattern includes an implantation region pattern.

23. The method of fabricating the shuttle wafer as claimed in claim 17, wherein the first die comprises a plurality of dies.
